(19) United States
(12) Patent Application Publication
(10) Pub. No.: US 2008/0087955 A1
(43) Pub. Date: Apr. 17, 2008

(54) Suction-Mountable Display Device

(75) Inventors: Douglas M. Sheffield, Chesterfield, MO (US); Tamara K. Sheffield, Chesterfield, MO (US)

Correspondence Address: ALSTON & BIRD LLP, BANK OF AMERICA PLAZA, 101 SOUTH TRYON STREET, SUITE 4000, CHARLOTTE, NC, 28280-4000, US

(73) Assignee: We-Flex, LLC

(21) Appl. No.: 11/550,012

(22) Filed: Oct. 17, 2006

(51) Int. Cl. H01L 29/76

(52) U.S. Cl. 257/335

(57) ABSTRACT

A deformable device mountable by suction on a smooth mounting surface. The device includes a body having an outer surface, a non-circular periphery extending around the body, surrounding the outer surface of the body and an inner surface opposite the outer surface having a concave portion. The device also includes a protrusion extending from the outer surface of the body including an exterior surface having a non-circular periphery. The body is deformable from an undeformed shape to an actuated shape to mount the body on the mounting surface by positioning the inner surface of the body adjacent the mounting surface when the body is undeformed thereby forming a cavity between the concave portion and the mounting surface and deforming the body to its actuated shape thereby sealing the body against the mounting surface and forcing fluid out of the cavity to create suction between the body and the mounting surface.

### BACKGROUND OF THE INVENTION

The present invention relates to suction-mountable display devices and, more particularly, to suction-mountable devices including a base having a non-circular shape and a protrusion having a non-circular shape corresponding to or differing from the shape of the base.

Most conventional vacuum-mountable devices include a flexible body having a circular periphery extending around the body and knobs extending from an outer surface of the body. The knobs generally have circular peripheries and are usually used for hanging items therefrom. Vacuum-mountable devices are sought having non-circular bodies and non-circular protrusions communicating themes and messages, for being aesthetic, and/or for holding items.

Circular bodies are common because reflex or spring forces developed within them are naturally distributed in a uniform circular pattern. When a vacuum-mountable device is deformed from an undeformed shape, reflex forces are created within its body that act to return the body to its undeformed shape. When the body is deformed and the device is mounted on a surface by vacuum, the reflex forces act to push the body away from the surface while vacuum forces created between the device body and the surface work to hold the device against the surface. The vacuum forces must be greater than the sum of the reflex forces created in the body to create and maintain a connection between the body and the surface. The reflex forces developed in non-circular bodies during deformation are generally distributed in a non-circular manner around the body. Vacuum forces between the body and the mounting surface do not balance well with non-uniform reflex forces for keeping the device mounted on the surface.

Some conventional vacuum-mountable devices having non-circular peripheries reduce the effect of non-circular reflex forces by tapering a thickness of the body towards the periphery. Such a device is designated in its entirety by reference numeral 10 in FIG. 1. The device 10 includes a flexible body 12 having an inner surface 14 and an outer surface 16 opposite the inner surface. The inner surface 14 includes a concave portion 18 and the outer surface 16 may include a convex portion 20. The body 12 includes a periphery 22 extending around the body and surrounding the outer surface 16. Example shapes for the periphery 22 include a heart shape (see e.g., FIG. 2a), a fish shape, and a star shape. A thickness T measured between the inner surface 14 and the outer surface 16 of the body 12 decreases toward the periphery 22 of the body. The reflex forces developed during deformation of tapered bodies 12 are more uniform because there is less material nearer the periphery 22 where the body is non-uniformly shaped. The body 12 near the periphery 22 contributes less to the reflex forces of the body in proportion to the decreased thickness T, allowing the reflex forces distributed more uniformly around a central portion 24 of the body to predominate the sum of the reflex forces. By developing more uniform reflex forces in the body 12, devices 10 having a tapered thickness T can securely mount on mounting surfaces 26.

Another way to reduce non-uniform reflex forces created within the flexible body 12 is to form a bend 28 in the body in which the body curves away from the mounting surface 26 between a suction portion 30 of the inner surface 14 of the device 10 and the periphery 22 of the device. The bending approach to reducing non-uniform reflex forces in the body 12 may be used in combination with the tapered thickness approach described in the preceding paragraph or instead of the tapered thickness approach. FIG. 1 illustrates the combination of the bent body and the tapered thickness in one device 10. The suction portion 30 of the inner surface 14 is contiguous with suction created between the body 12 and the mounting surface 26 to mount the device 10 on the mounting surface. That is, the suction portion 30 consists of the surface of the body 12 that interacts with the mounting surface 26 to create the suction mounting the device 10 on the mounting surface. The suction portion 30 includes the concave portion 18 of the inner surface 14 and has a boundary 32 extending around and defining the suction portion. The inner surface 14 also includes an additional portion 34 between the suction portion 30 and the periphery 22. The additional portion 34 is not needed for creating suction to mount the device 10 on the mounting surface 26. The bend 28 is adjacent the boundary 32 of the suction portion 30 and between the suction portion and the periphery 22. The bend 28 reduces the sum of reflex forces within the body 12 because material of the body that is bent away from the mounting surface 26 pushes less toward the mounting surface when the device 10 is mounted on the mounting surface thereby increasing a likelihood of successful mounting and decreasing a likelihood of demounting.

### BRIEF SUMMARY OF THE INVENTION

The present invention relates to a deformable device mountable by suction on a generally smooth mounting surface. The device includes a body having an outer surface, a non-circular periphery extending around the body, surrounding the outer surface of the body and an inner surface opposite the outer surface having a concave portion. The device also includes a protrusion extending from the outer surface of the body including an exterior surface having a non-circular periphery. The body is deformable from an undeformed shape to an actuated shape to mount the body on the mounting surface by positioning the inner surface of the body adjacent the mounting surface when the body is in the undeformed shape thereby forming a cavity between the concave portion and the mounting surface and deforming the body to its actuated shape thereby sealing the body against the mounting surface and forcing fluid out of the cavity to create suction between the body and the mounting surface thereby securing the body to the mounting surface.

In another aspect, the present invention relates to a deformable device mountable by suction on a generally smooth mounting surface including a body including an inner surface having a concave portion and an outer surface opposite the inner surface having a central portion. The body further includes a periphery extending around the body, surrounding the outer surface and the inner surface of the body. The device further includes a protrusion extending from the outer surface of the body including a head having an interior surface, an exterior surface opposite the interior surface of the head, and a periphery extending around the head and surrounding the exterior surface. The protrusion is attached to the outer surface of the body at a portion of the outer surface of the body other than the central portion of the outer surface of the body. The body is deformable from an undeformed shape to an actuated shape to mount the body on the mounting surface by positioning the inner surface of the body adjacent the mounting surface when the body is in the undeformed shape thereby forming a cavity between the concave portion and the mounting surface and deforming the body to its actuated shape thereby sealing the body against the mounting surface and forcing fluid out of the cavity to create suction between the body and the mounting surface thereby securing the body to the mounting surface.

In yet another aspect, the present invention relates to a deformable device mountable by suction on a generally smooth mounting surface including a body including an inner surface having a concave portion and an outer surface opposite the inner surface having a central portion. The body also includes a periphery extending around the body, surrounding the outer surface and the inner surface of the body. The device further includes a protrusion extending from the outer surface of the body including a stem connected to the outer surface of the body, a head having an exterior surface and an interior surface opposite the exterior surface connected to the stem, and a periphery extending around the head and surrounding the exterior and interior surfaces. The interior surface of the head includes a central portion and the stem is attached to the interior surface of the head at a portion of the interior surface of the head other than the central portion of the interior surface of the head. The body is deformable from an undeformed shape to an actuated shape to mount the body on the mounting surface by positioning the inner surface of the body adjacent the mounting surface when the body is in the undeformed shape thereby forming a cavity between the concave portion and the mounting surface and deforming the body to its actuated shape thereby sealing the body against the mounting surface and forcing fluid out of the cavity to create suction between the body and the mounting surface thereby securing the body to the mounting surface.

Other aspects of the present invention will be in part apparent and in part pointed out hereinafter.

### BRIEF DESCRIPTION OF THE DRAWINGS

FIG. 1 is a cross-sectional view of a conventional vacuum-mountable device positioned adjacent a mounting surface.

FIG. 2a is a perspective of a vacuum-mountable device according to a first embodiment of the present invention.

FIG. 2b is a cross section of the device taken along line b-b of FIG. 2a shown in an undeformed shape adjacent the mounting surface.

FIG. 2c is a cross section of the device taken along line b-b of FIG. 2a shown in an actuated shape secured to the mounting surface.

FIG. 2d is a front elevation of the device shown in FIG. 2a.

FIG. 3 is a perspective of a vacuum-mountable device according to a second embodiment of the present invention.

FIG. 4 is a perspective of a vacuum-mountable device according to a third embodiment of the present invention.

FIG. 5 is a perspective of a vacuum-mountable device according to a fourth embodiment of the present invention.

FIG. 6 is a perspective of a vacuum-mountable device according to a fifth embodiment of the present invention.

FIG. 7 is a perspective of a vacuum-mountable device according to a sixth embodiment of the present invention.

FIG. 8 is a perspective of a vacuum-mountable device according to a seventh embodiment of the present invention.

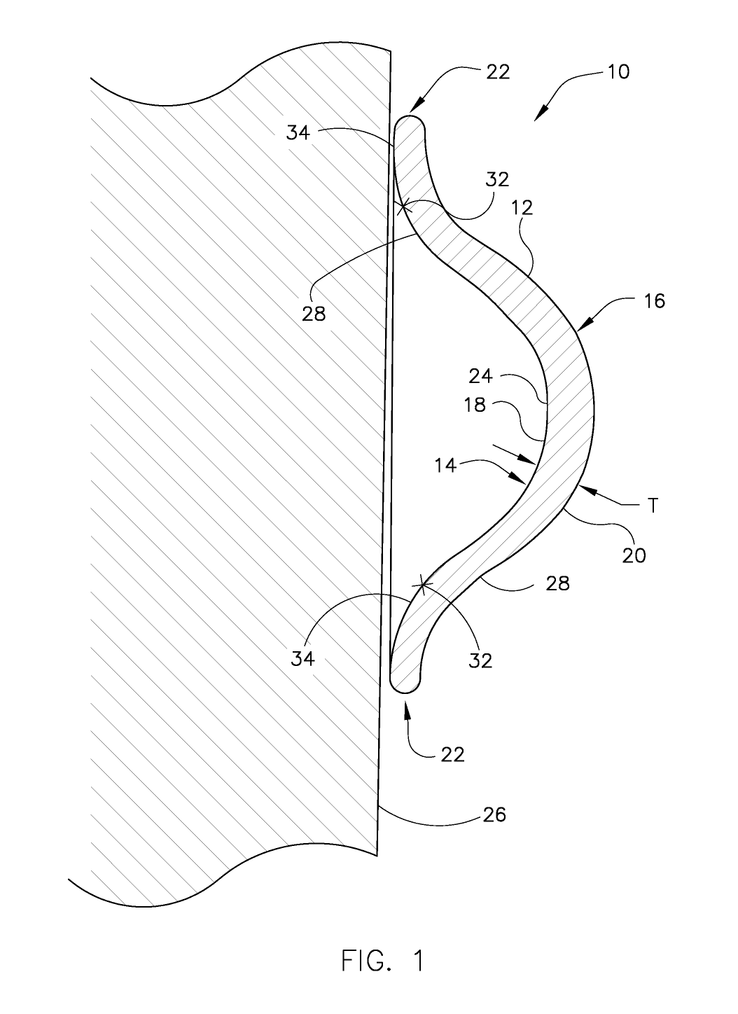

Corresponding reference characters indicate corresponding parts throughout the several views of the drawings.

### DETAILED DESCRIPTION OF THE INVENTION

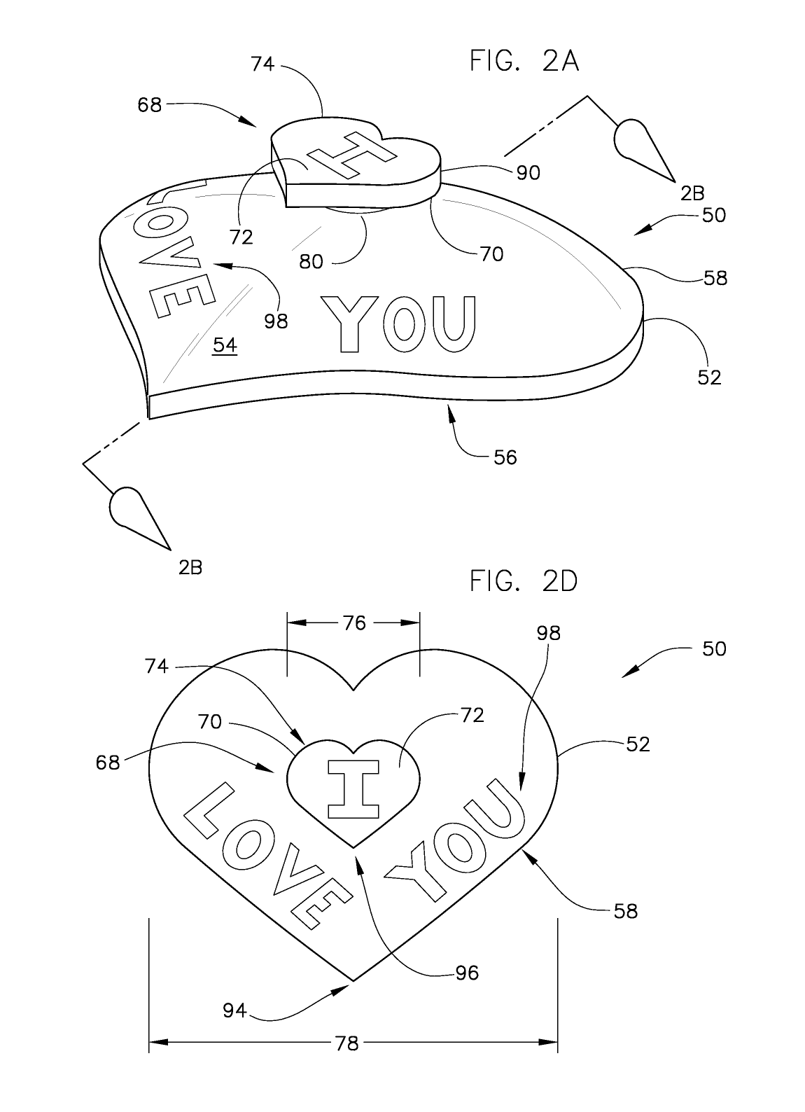

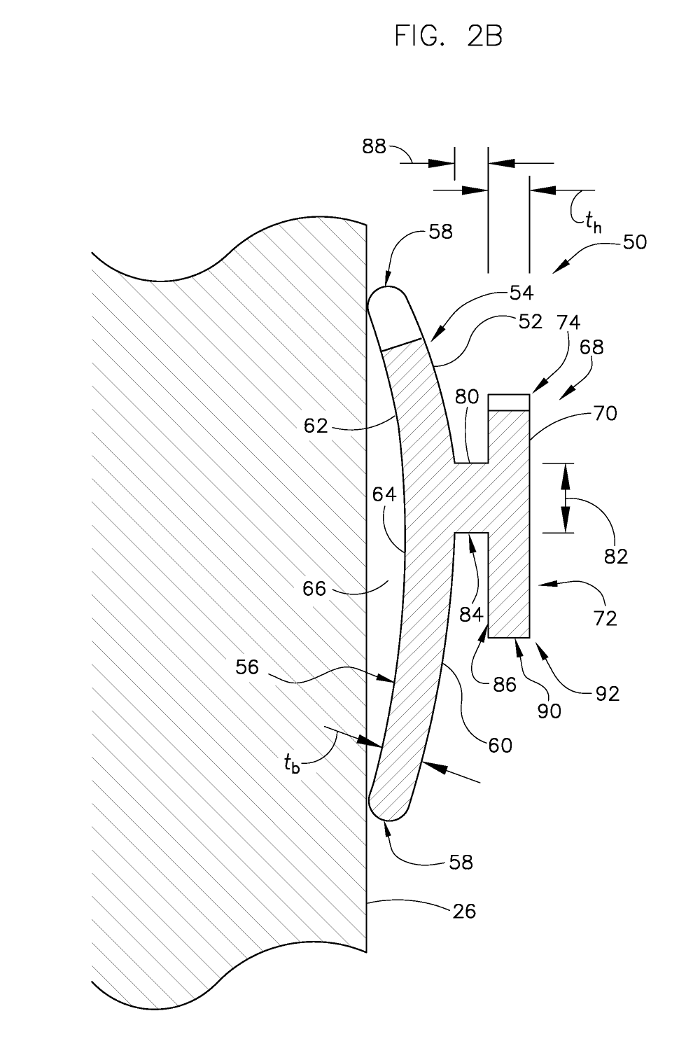

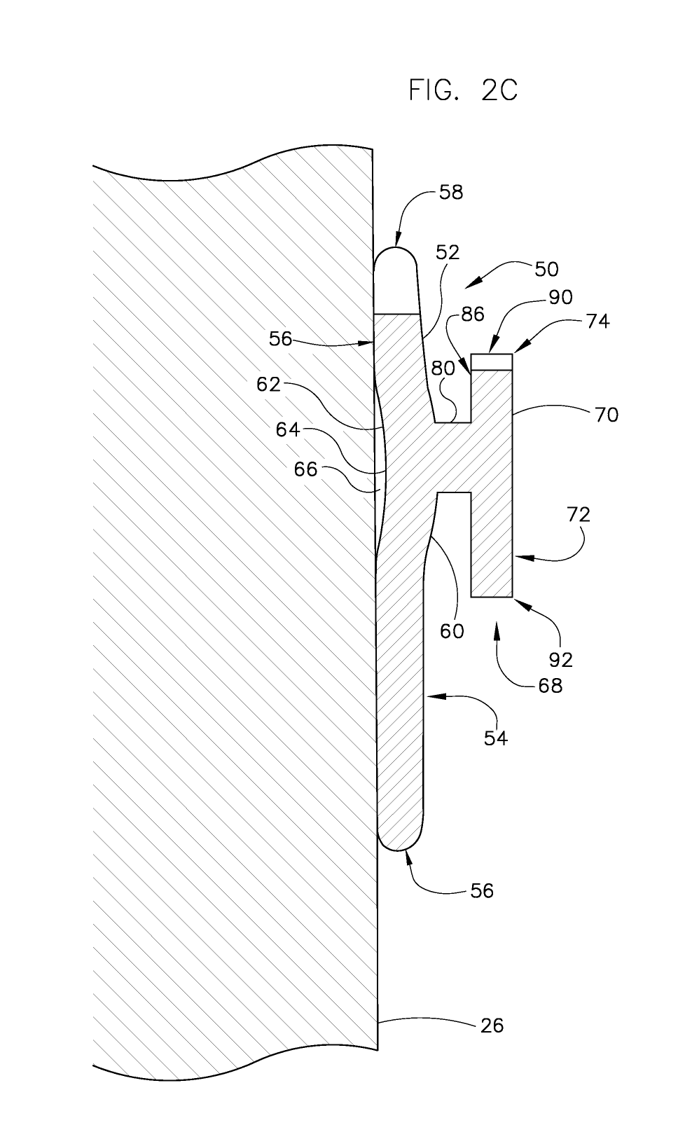

Referring to the figures, and more particularly to FIG. 2a, a portable display device according to a first embodiment of the present invention is designated in its entirety by reference number 50. The display device 50 has a flexible or deformable body 52 including an outer surface 54, an inner surface 56 opposite the outer surface, and a periphery 58 extending around the body and surrounding the inner surface and the outer surface. Although the flexible body 52 may include other materials without departing from the scope of the present invention, in one embodiment the body includes a resinous thermoplastic such as polyvinyl chloride. As shown in FIG. 2b, the outer surface 54 may include a convex portion 60. The inner surface 56 includes a concave portion 62 opposite the outer surface 54. The concave portion 62 of the inner surface 56 has a center 64. For embodiments in which the outer surface 54 includes the convex portion 60, the concave portion 62 of the inner surface 56 may be opposite the convex portion.

The flexible body 52 has a thickness t_{b} measured between the outer surface 54 and the inner surface 56. The thickness t_{b} may vary throughout the flexible body 52 or be generally constant. For example, the thickness t_{b} may vary from a maximum thickness of between about 0.10 inch and about 0.25 inch adjacent the center 64 of the concave portion 62 and a minimum thickness of between about 0.045 inch and about 0.125 inch adjacent the periphery 58. As described in the Background of the Invention section above, a tapered thickness increases uniformity of reflex forces developed in a non-uniformly-shaped body during deformation of the body, allowing the body to be securely mounted on mounting surfaces 26.

Reflex forces can also be reduced by varying the material or material properties of the flexible body 52 between the center 64 and the periphery 58. For example, the material of the body 52 may be less resilient adjacent the periphery to reduce reflex forces created by the body adjacent the periphery.

Also described above as a way to develop more uniform reflex forces in a nonuniform-shaped body, the inner surface 56 may include a bend (similar to the bend 28 described above) adjacent a boundary of a suction portion of the inner surface (similar to the boundary 32 and the suction portion 30 described above). The bend may be positioned between the boundary of the suction portion and the periphery 58 of the body. The suction portion consists of the surface of the body 52 that interacts with the mounting surface 26 to create the suction mounting the device 50 on the mounting surface. The suction portion includes the concave portion 62 of the inner surface 56 and the boundary extends around and defines the suction portion. The body 52 further includes an additional portion (similar to the additional portion 34 described above) between the suction portion and the periphery 58. Although the bend may change a direction of the inner surface 56 by other amounts when the flexible body 52 is undeformed, in one embodiment the bend changes the direction of the inner surface by between about 5° and about 20° when the flexible body is undeformed. The body 52 may have any combination of a tapered body thickness, varying body material, varying material properties, and a bend adjacent a boundary of a suction portion of the inner surface.

The flexible body 52 is deformable between an undeformed or default shape, shown in FIG. 2b, and an actuated shape, shown in FIG. 2c, to mount the display device 50 by suction or vacuum on the mounting surface 26. The display device 50 may be secured to mounting surfaces 26 having various attitudes. For example, the display device 50 may be mounted on an upward facing or downward facing horizontal mounting surface 26. The display device 50 may also be mounted on a vertical surface 26 or on a generally upward or downward facing surface angled between horizontal and vertical. A mounting strength of the display device 50 depends in part on the size, shape, and material of the display device and characteristics of the mounting surface 26, such as smoothness.

The mounting surface 26 must include a surface area that is at least as large as an area spanned by the suction portion (described above) of the inner surface 56 of the body 52 when the flexible body is in its actuated shape. To mount the display device 50 on the mounting surface 26, the inner surface 56 of the flexible body 52 is positioned adjacent the mounting surface when the body is in its default shape, as shown in FIG. 2b. By positioning the flexible body 52 in this way, a cavity 66 is formed between the suction portion of the body and the mounting surface 26.

After the flexible body 52 is positioned adjacent the mounting surface 26 as described, the flexible body is moved to its actuated shape (i.e., causing the inner surface 56 to conform to the mounting surface), as shown in FIG. 2c, thereby sealing the body against the mounting surface and forcing fluid such as air out of the cavity 66. The suction created within the sealed cavity 66 secures the body 52 to the mounting surface 26. As the flexible body 52 is deformed toward the actuated shape, reflex or spring forces are created in the body between the convex and concave portions 60, 62 that act to return the body to its default shape thereby creating the suction between the body and the mounting surface. As will be appreciated by those skilled in the art, the flexible body 52 must be sized and shaped so forces created by the suction are balanced with or are greater than the sum of the reflex forces created in the body and any loading on the body to create and maintain the connection between the body and mounting surface 26.

To demount the flexible body 52 from the mounting surface 26, for example to relocate the display device 50 on another smooth mounting surface, the body is moved out of its actuated shape thereby breaking the seal and suction. To break the seal and move the body 52 out of its actuated shape, the user may move or pull on a portion of the periphery 58 of the body.

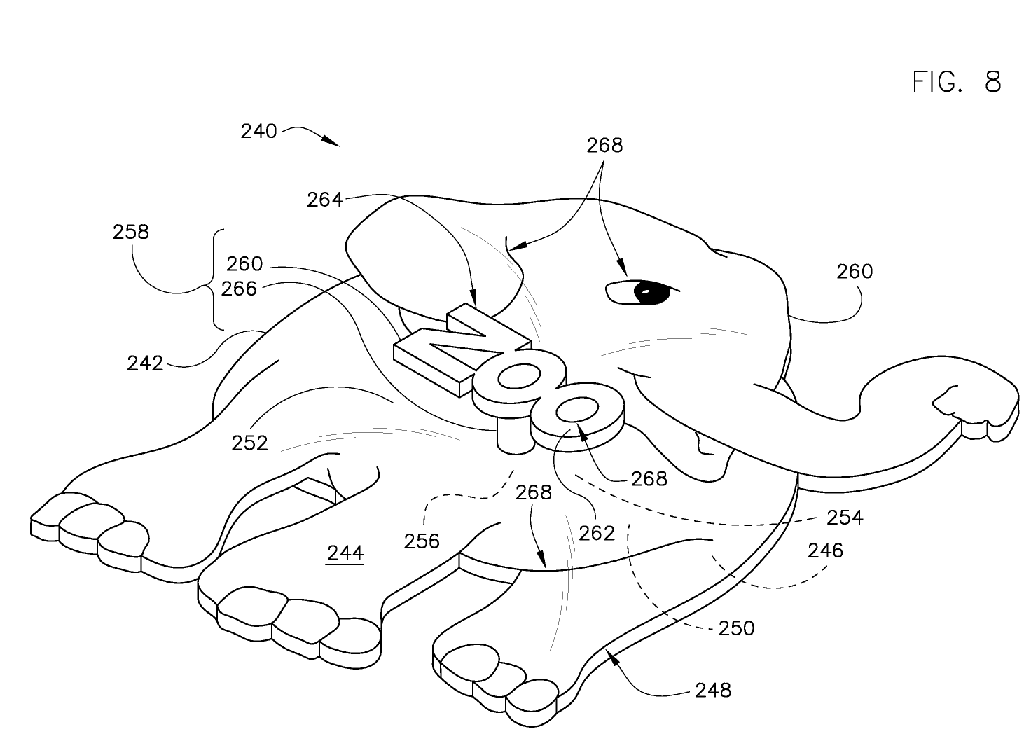

As described above, the additional portion of the inner surface 56 between the suction portion and the periphery 58 of the body is not needed to create the suction used to mount the device 50 on the mounting surface 26. The additional portion and the periphery 58 surrounding the additional portion may have various sizes and shapes without departing from the scope of the present invention, as long as the suction between the body 52 and the mounting surface 26 can be created and maintained as described above. FIGS. 2a-2d show an embodiment of the display device 50 in which the periphery 58 is shaped as a heart. The periphery 58 may be symmetric, such as circular, square, or oval, or non-symmetric. In one embodiment, the periphery 58 is non-circular. Other exemplary periphery 58 shapes include those corresponding to articles of clothing such as a shirt or shoe, structures such as a bridge or skyscraper, a vehicle such as a car, boat, or airplane, and articles of nature such as a fruit, flower, tree, person, or animal. The periphery 58 of the body 52 may also be shaped to form symbols such as letters (see e.g., FIG. 8) or numbers.

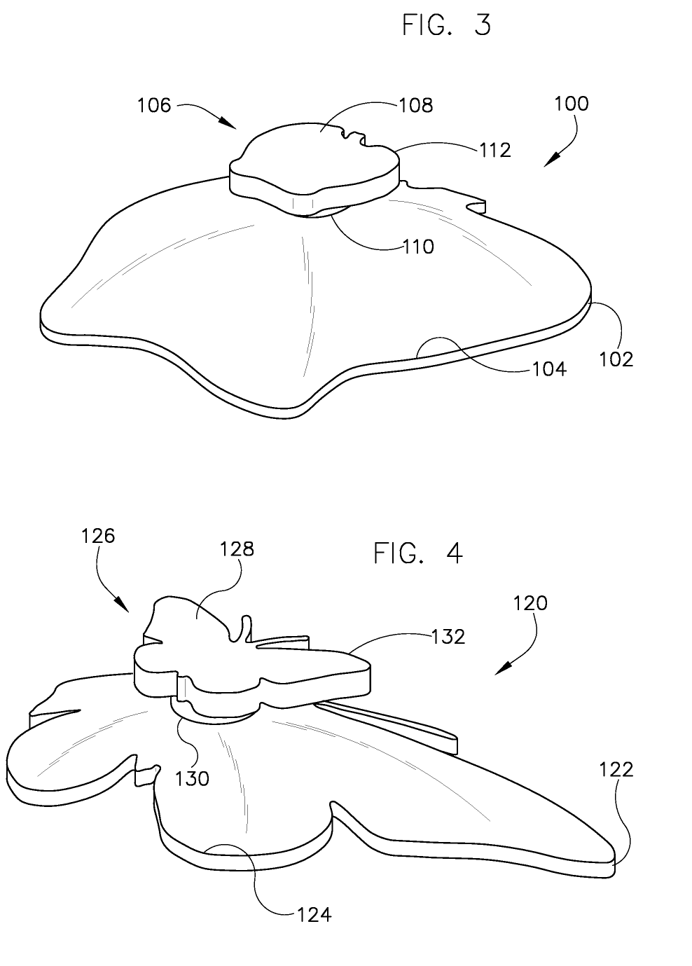

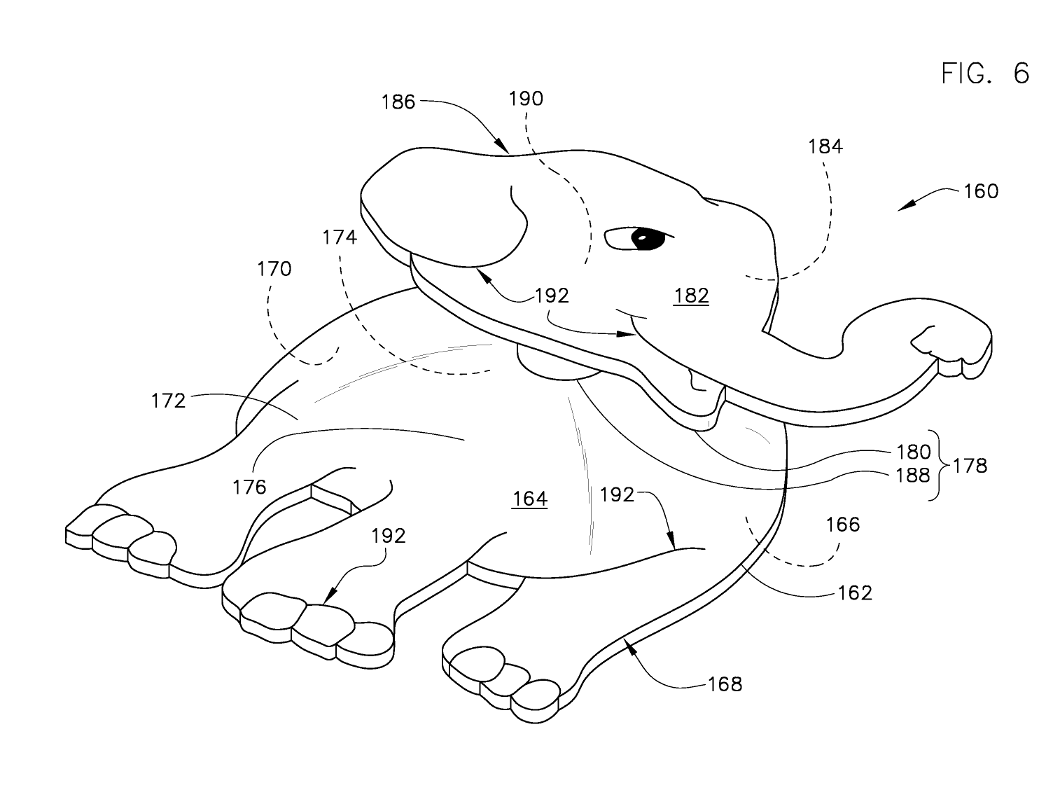

The body 52 may be colored or tinted as desired and the color or tint may correspond to a shape of the periphery 58 of the body. For example, a body 52 shaped as an apple (see e.g., FIG. 3) may be colored or tinted green and/or red. Also, the body 52 may include marks and/or other accents corresponding to the shape of the periphery 58 of the body. The accents may include textured, raised, and lowered portions of the base body material or other material attached to the body 52. For example, in one embodiment (not shown) the body 52 has a periphery 58 shaped like a head of a person and includes colors and markings printed on the outer surface 54 of the body forming details (e.g., eyes, nose, and mouth) of the person's face. The marks and accents may be printed on the outer surface 54 or on the inner surface 56 of the body 52. The marks and accents may be printed on a label adhered to the outer surface 54 and the label may be fully or partially opaque, translucent, and/or transparent as desired. It is contemplated that the marks or accents may be formed using material of the flexible body 52 by, for example, molding, melting, etching, engraving, doping, or impressing. Also, as described below in further detail, the marks and accents may also be formed on a protrusion extending from the body in the same manners described above. FIGS. 6-8 show embodiments of devices 160, 200, 240, described in further detail below, including marks and/or accents 192, 228, 268 formed on a body 162, 202, 242 and/or a protrusion 178, 218, 258 extending from the body forming details of the item or object represented by the shape of the body or protrusion. The terms “item” and “object” are used in broad senses. Exemplary items include but are not limited to a person, an animal, common geometric shapes such as a triangle and a hexagon, a vehicle such as a car or airplane, a building, and everyday articles such as a clock or a tennis racket.

The device 50 also includes a protrusion 68 extending from the outer surface 54 of the body 52. The protrusion 68 and the body 52 may be unitary (e.g., formed unitarily), as shown in FIG. 2b, or separate connected pieces. The protrusion 68 includes a head 70 having an outer or exterior surface 72 and a periphery 74 extending around the protrusion and surrounding the exterior surface of the head. Although the head 70 may have other maximum widths 76 (shown in FIG. 2d) measured between two points on the periphery 74 of the protrusion 68 without departing from the scope of the present invention, in one embodiment the head has a maximum width of between about 0.5 inch and about 1.25 inches. In one embodiment, the maximum width 76 of the head 70 is between about 30% and about 100% of a maximum width 78 of the body 52 measured between two points on the periphery 58 of the body. That is, the maximum width 76 of the head 70 may be between about 30% of the maximum width 78 of the body 52 and about the same as the maximum width of the body. The maximum width 76 of the head 70 may also be greater than the maximum width 78 of the body 52.

Particular advantages may result from having the body 52 extend laterally farther than the protrusion 74, and vice versa, at all places or selectively about the device 50. In one exemplary application of devices 50 having a protrusion that is wider in places than a corresponding width of the body, the head accents the body from behind the body when the device is mounted on a mounting surface 26 of a transparent substrate (e.g., a storefront window) and a viewer views the device from a side (e.g., a street side) of the substrate that is opposite the mounting surface. For example, in one embodiment (not shown) the periphery 58 of the body 52 forms a shape of an angel without wings and the periphery 74 of the protrusion 68 forms a shape of the angel's wings that extends laterally beyond the width of the body in places to provide a three-dimensional effect of the angel having wings extending naturally from the angel. Such an arrangement creates a three-dimensional effect because the part of the item formed by the body (i.e., the angel sans wings) is closer to the viewer of the device than the part (i.e., the wings) formed by the body when the viewer views the device from the nonmounting side of the substrate.

The head 70 may be connected directly to the body 52 or the protrusion 68 may include a stem 80 connecting the head and the outer surface 54 of the body as shown in FIG. 2b. Although the stem 80 may have other shapes without departing from the scope of the present invention, in one embodiment the stem is generally cylindrical. Although the stem 80 may have other maximum widths 82 (shown in FIG. 2b) measured between two points on an exterior surface 84 of the stem without departing from the scope of the present invention, in one embodiment the stem has a maximum width of between about 0.2 inch and about 0.5 inch. In one particular embodiment, the stem 80 has a maximum width 82 of between about 0.3125 inch and about 0.4275 inch. In one embodiment, the maximum width 82 of the stem 80 is between about 10% and about 50% of the maximum width 76 of the head 70.

The exterior surface 72 of the head 70 may be generally planar and, as shown in FIG. 2c, may be generally parallel to the mounting surface 26 when the device 50 is mounted on the mounting surface. The head 70 may also include an inner or interior surface 86 (shown in FIG. 2b) opposite the exterior surface 72 of the head. In one embodiment, the interior surface 86 of the head 70 is generally planar and in a particular embodiment the interior surface 86 is generally planar and generally parallel to the exterior surface 72 of the head. Although the head 70 of the protrusion 68 and the outer surface 54 of the body 52 may be separated by other minimum distances 88 without departing from the scope of the present invention, in one embodiment the head and the outer surface of the body are separated by a minimum distance of between about 0.05 inch and about 0.2 inch. In one particular embodiment, the head 70 and the outer surface 54 of the body 52 are separated by a minimum distance 88 of between about 0.0875 inch and about 0.125 inch.

Although the head 70 may have other maximum thicknesses tₕ measured between the exterior surface 72 and the interior surface 86 of the head, in one embodiment the head has a maximum thickness between about 0.05 inch and about 0.2 inch. In one particular embodiment, the head 70 has a maximum thickness tₕ between about 0.0875 inch and about 0.150 inch. The head 70 may have a varying or a generally constant thickness tₕ. In one embodiment, the thickness tₕ of the head 70 is between about 70% and about 100% of the thickness t_{b} of the body 52. That is, the thickness tₕ of the head 70 may be between about 70% of the thickness t_{b} of the body 52 and about the same as thickness of the body. The thickness tₕ of the head 70 may also be greater than the thickness t_{b} of the body.

The head 70 of the protrusion 68 further includes a side wall 90 between the exterior surface 72 and the interior surface 86 of the protrusion. An intersection 92 between the side wall 90 and the exterior surface 72 of the protrusion 68 defines the periphery 74 of the protrusion. In one embodiment, the side wall 90 of the head 70 is generally perpendicular to the exterior surface 72 and/or the interior surface 86 of the protrusion 68.

The periphery 74 of the protrusion 68 may have various shapes without departing from the scope of the present invention. The periphery 74 of the protrusion 68 may be symmetric, such as circular, square, or oval, or non-symmetric. In one embodiment, the periphery 74 of the protrusion 68 is non-circular. Exemplary shapes for the periphery 74 of the protrusion 68 include those corresponding to articles of clothing such as a shirt or shoe, structures such as a bridge or skyscraper, a vehicle such as a car, boat, or airplane, and articles of nature such as a fruit, flower, tree, person, or animal. Also, the protrusion 68 may be colored or tinted as desired and the color or tint may correspond to a shape of the periphery 74 of the protrusion and/or a shape of the periphery 58 of the body 52. For example, a protrusion 68 shaped as an apple (see e.g., FIG. 3) may be colored or tinted green and/or red. Also, the color or tint of the body 52 may correspond to the shape of the protrusion 68 and/or the shape of the body 52.

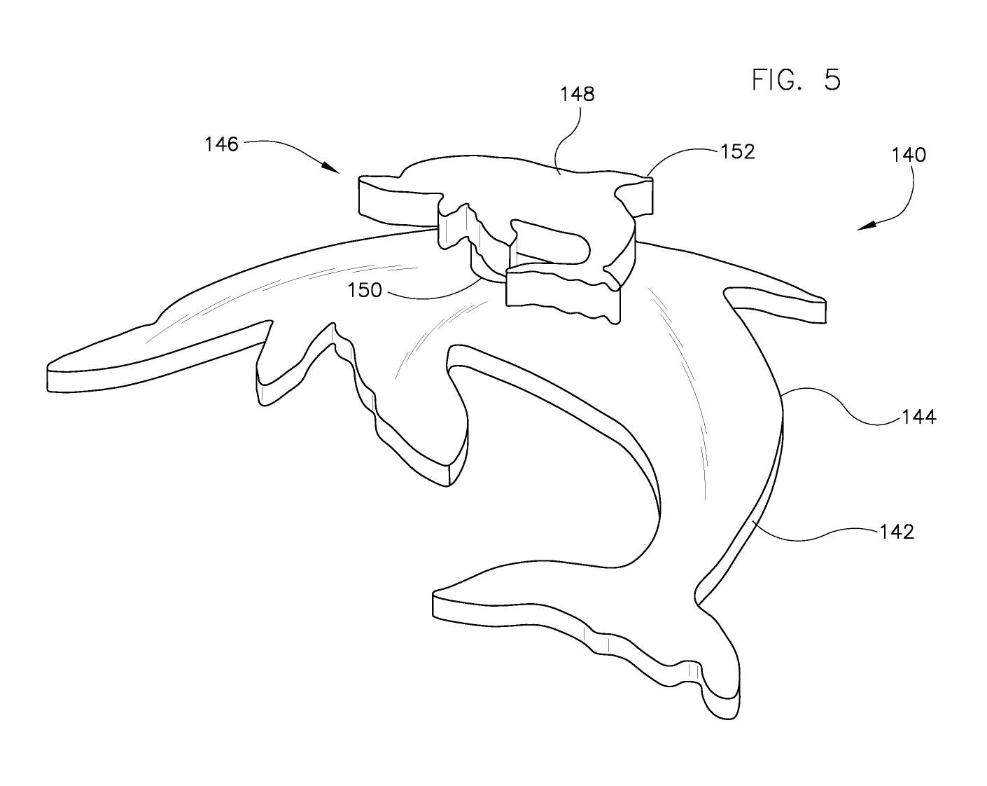

The protrusion 68 may form objects in three dimensions. For example, the head 70 may form a three-dimensional baseball by being generally spherical and colored white and including raised portions colored red forming stitching of the ball. As another example, a head having a periphery shaped as a dolphin (similar to the head 148 shown in FIG. 5) may also include raised and/or lowered portions forming portions (e.g., a rounded body, fins, flippers, flukes, eye sockets, and a blow hole) of the dolphin. Further in this embodiment, the head forming the dolphin shape may be colored blue and include marks (e.g., black printed lines) forming details of the dolphin, such as details of the body, an eye, and the blow hole.

The shape of the periphery 74 of the protrusion 68 and the shape of the periphery 58 of the body 52 may be generally the same. For example, in the device 50 shown in FIGS. 2a-2d, the periphery 74 of the protrusion 68 and the periphery 58 of the body 52 are both heart shaped. The same-shaped peripheries 58, 74 may be oriented in the same way. The peripheries 58, 74 shown in FIGS. 2a-2d are oriented in the same direction. For example, points or cusps 94, 96 of heart-shaped peripheries 58, 74 point in the same direction (e.g., downward in FIG. 2d). In some embodiments (not shown), the peripheries 58, 74 are oriented differently. That is, the orientation of the periphery 74 of the protrusion 68 may be angularly offset from the orientation of the periphery 58 of the body 52. For example, the point 94 of the body 52 may point upward in FIG. 2d and the point 96 of the protrusion 68 may point downward, representing an offset of 180°. The same-shaped peripheries 58, 74 may be offset by any amount (i.e., between 0° and about 180°).

In some embodiments, the shape of the periphery 74 of the protrusion 68 is different from the shape of the periphery 58 of the body 52. For example, in one particular embodiment the periphery 74 of the protrusion 68 is heart-shaped (see e.g., periphery 74 in FIG. 2a) and the periphery 58 of the body 52 is shaped as a butterfly (see e.g., periphery 124 in FIG. 4). FIGS. 6-8 show embodiments of devices 160, 200, 240, described in further detail below, including bodies and protrusions having different shapes from each other.

The shapes of the peripheries 58, 74 of the body 52 and the protrusion 68 may correspond to each other. That is, the periphery 74 of the protrusion 68 may be shaped as an item that is related to an item that the periphery 58 of the body 52 is shaped as. One example of the peripheries 58, 74 corresponding to each other is the peripheries having the same shape. As another example of the peripheries corresponding to one another, in one embodiment (not shown) the periphery 58 of the body 52 is shaped as a flower and the periphery 74 of the protrusion 68 is shaped as a butterfly. The butterfly shape corresponds to the flower shape because butterflies often land on flowers in nature. In another embodiment (not shown), the periphery 58 of the body 52 is shaped as a foot_{b}all helmet and the periphery 74 of the protrusion 68 is shaped as a foot_{b}all. In another exemplary embodiment (not shown), the periphery 58 of the body 52 is shaped as a baseball hat and the periphery 74 of the protrusion 68 is shaped and colored as a baseball and/or a baseball bat.

As another example of the peripheries 58, 74 of the body 52 and the protrusion 68 corresponding to each other, the periphery of the body may be shaped as an item or a portion of the item and the periphery of the protrusion may be shaped as a part of or accessory to that item. This arrangement creates a three-dimensional effect because the part of the item formed by the protrusion is closer to the viewer of the device than the item or item part formed by the body. For example, the periphery 58 of the body 52 may be shaped as an animal, such as a duck, and the periphery 74 of the protrusion 68 may be shaped as a part of the animal, such as a wing, beak, or entire head of the duck. FIG. 6 shows an embodiment of a device 160, described in further detail below, including a body 162 having a periphery 168 shaped as a body of an elephant and a protrusion 178 extending from the body having a periphery 186 shaped as a head of the elephant.

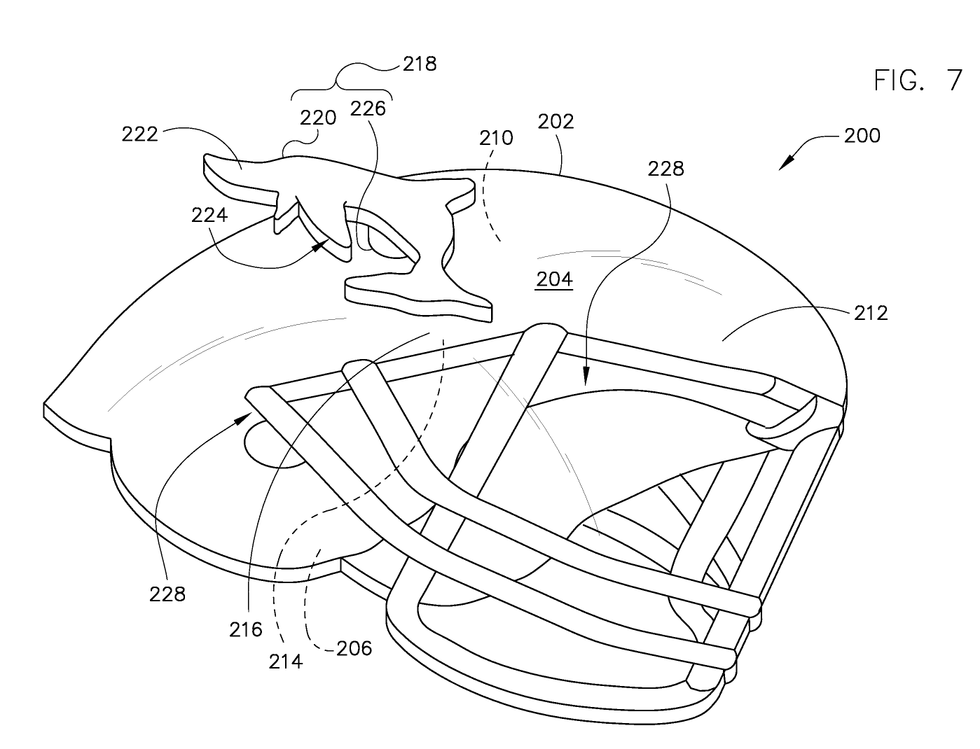

As another example of the periphery 58 of the body 52 being shaped as an item or portion of the item and the periphery 74 of the protrusion 68 being shaped as a part of or related to that item, the periphery of the body may be shaped as part of an athletic uniform and the periphery of the protrusion may be shaped as another part or a subpart of the uniform. For example, in one embodiment (not shown), the periphery 58 of the body 52 is shaped as a hockey jersey and the periphery 74 of the protrusion 68 is shaped as a mascot (e.g., a tiger), an emblem (e.g., a school or company logo), or player number. FIG. 7 shows an embodiment of a device 200, described in further detail below, including a body 202 having a periphery 208 shaped as a foot_{b}all helmet and a protrusion 218 extending from the body having a periphery 224 shaped as a dolphin mascot (e.g., of a high school foot_{b}all team). In another exemplary embodiment (not shown), the periphery of the body is shaped as a baseball bat and the periphery of the protrusion is shaped as a baseball and includes, for example, coloring and simulation of stitching.

As yet another example of the peripheries 58, 74 of the body 52 and the protrusion 68 corresponding to each other, the periphery of the body may be shaped as an item and the periphery of the protrusion may be shaped as words associated with the item. For example, the body 52 may form the shape of an animal and the protrusion 68 may be shaped to form letters forming a word describing or otherwise related to the animal, such as a type of animal (e.g., “TURTLE” or “HIPPO”). FIG. 8 shows an embodiment of a device 240, described in further detail below, including a body 242 having a periphery 248 shaped as an elephant and a protrusion 258 having a periphery 264 shaped to form the word “ZOO”. As another exemplary embodiment (not shown), the periphery of the body of the device may be shaped as a flower and the periphery of the protrusion may be shaped to form word “FLORIST”, the letters of a florist's name, or contact information (e.g., a phone number) for the florist. As yet another example, the body of the device may form the shape of a sports implement such as a jersey or helmet and the protrusion may form letters spelling the name of a home city (e.g., “ST. LOUIS”) or the name of a mascot (e.g., “ANGELS”) of a sports franchise, thereby promoting the franchise. As still another example, the periphery 58, 74 of the body 52 and/or the protrusion 68 may also form letters that are personal to a person, such as the first letter of their first or last name, their initials, or their complete name. Further in this example, the person may desire a device 50 having body 52 shaped as an item, such as an animal, that the person is particularly fond of and a protrusion 68 forming the first letter of their first or last name, their initials, or their complete name. The particular related periphery 58, 74 shapes described herein are only exemplary and the device 50 may be designed to include peripheries having many other related shapes.

The shapes of the peripheries 58, 74 may be designed to communicate messages or themes. For example, in one embodiment (not shown) each periphery 58, 74 is shaped as an arrow and the arrows point in the same direction (i.e., the peripheries have the same orientation). The arrow-shaped device can be used to indicate a particular direction or to point to an item. For example, an arrow-shaped device including material that glows in the dark can be secured to a wall adjacent and pointing to a door in a darkened room such as a movie theater or an x-ray room. In this example, the arrow-shaped device would indicate a location of the door or doorknob. As another example of the peripheries 58, 74 communicating messages, the periphery of the body 52 may be shaped as a cigarette and the periphery of the protrusion 68 may be shaped as a circle having a bar through it colored red indicating that smoking is prohibited in the area where the device is mounted. As yet another example, the periphery 58 of the body 52 may be shaped as an arrow and the periphery 74 of the protrusion 68 may be shaped as the circle having the bar through it colored red indicating that the viewer of the device 50 should not go in a direction that the arrow-shaped body is pointing.

In another embodiment of the peripheries communicating messages, the periphery 58 of the body 52 may be shaped as part of an athletic uniform, such as a baseball bat, a foot_{b}all helmet, or a soccer jersey, and the periphery 74 of the protrusion 68 may be shaped as another part or a subpart of the uniform or implement, such as a baseball in combination with the baseball bat-shaped body and a mascot, logo, or player number in combination with the helmet or jersey. The particular periphery 58, 74 shapes communicating messages described herein are only exemplary and the device 50 may be designed to include peripheries communicating many other things in various ways.

In one embodiment, the peripheries 58, 74 have shapes relating to an entity using the device, such as a store or restaurant. For example, the peripheries 58, 74 of the body 52 and/or the protrusion 68 may be shaped as apples (FIG. 3) and used at a fruit market and/or as an advertisement for the market. The peripheries 58, 74 of the body 52 and the protrusion 68 may have different shapes relating to the same message or theme. For example, in one embodiment (not shown) the periphery 58 of the body 52 is shaped as an apple and the periphery 74 of the protrusion 68 is shaped as another fruit, such as a banana. The fruit-shaped peripheries of these examples may communicate, among other things, that fruit is sold in the area where the devices are mounted. As another example, the periphery 58 of the body 52 may be shaped as an apple and the periphery 74 of the protrusion 68 may be shaped as a fish to indicate that produce and seafood are sold in the area where the device is mounted. The particular periphery 58, 74 shapes relating to an entity described herein are only exemplary and the device 50 may be designed to include peripheries having shapes relating to various other entities in various ways.

The periphery shapes 58, 74 may communicate a theme of a company or person's trade. For example, the periphery may be shaped as a dolphin (see e.g., FIG. 5) communicating, among other things, that the user of the device works with such animals. A dolphin-shaped periphery may also communicate, among other things, that the person using the device is fond of dolphins. As another example, the periphery may be shaped as a house and used by a real estate agent or home builder to communicate their trade and/or for advertising purposes. The particular messages that the periphery 58, 74 shapes may communicate described herein are only exemplary and the message and themes that the device may be designed to communicate are not limited to these examples.

The exemplary periphery shapes described herein are not exclusive to the category that they are described with respect to. Accordingly, the examples provided in each category of the peripheries of the body and the protrusion corresponding to each other, communicating messages, relating to an entity, and communicating a theme of a company or person, may apply to each other. For example, although the example of a device including a body shaped as a flower and a protrusion forming the word “FLORIST” is described above with respect to the category of the peripheries corresponding to each other, this exemplary device also fits within the categories of having periphery shapes communicating messages, relating to an entity, and communicating a theme of a company or person.

As shown in FIGS. 2a and 2d, the device 50 may also include a message 98 displayed on the flexible body 52 and/or on the protrusion 68. The message 98 may be displayed on the outer surface 54 of the body 52, on the inner surface 56 of the body, and/or between them. In the embodiment illustrated in FIGS. 2a and 2d, the message 98 includes the letter “I” displayed on the exterior surface 72 of the head 70 and the words “LOVE” and “YOU” displayed on the outer surface 54 of the body 52. Various types of messages 98 may be formed and displayed on or in the flexible body 52 and/or protrusion 68 without departing from the scope of the present invention. For example, words, logos, and/or art may be formed and displayed on or in the flexible body 52 and/or the protrusion 68 for communication and/or aesthetic purposes. The message 98 may be secured to or formed on or in the body 52 or the protrusion 68 in various ways without departing from the scope of the present invention. For example, the message 98 may be printed on the outer surface 54 or on the inner surface 56 of the body 52. The message 98 may also be printed on a label adhered to one of the outer surfaces 54, 72 and the label may be fully or partially opaque, translucent, and/or transparent as desired. It is contemplated that the message 98 may be formed using material of the flexible body 52 and/or the protrusion 68 by, for example, molding, melting, etching, or engraving the message into the outer surface 54, 72 of the body and/or protrusion.

The message 98 may be colored as desired. The shape of the body 52, the shape of the protrusion 68, the color of the body, the color of the protrusion, the message 98, and the color of the message may be selected to relate to each another as desired. For example, in one embodiment (not shown), a golf-inspired display device includes a body shaped as a putting green (e.g., kidney-bean shaped) and colored green, a protrusion having a generally circular white-colored head, and a message including actual dimples or a rendition of dimples printed or otherwise displayed on the exterior surface of the head to look like a golf ball.

In one embodiment, the periphery 58 of the body 52 and/or the periphery 74 of the protrusion 68 may be shaped as a message, such as by being shaped as words, numbers, a logo, or a symbol, also as described above. For example, the body 52 may be shaped and accented (e.g., colored and/or textured) as a smiley face and the protrusion 68 may be shaped to form the letters “HELLO”. As another example, the body 52 may be shaped as a hand with the first two fingers forming a V shape (i.e., the popular manual sign for peace) and the protrusion 68 may be shaped to form the word “PEACE”. As yet another example, the body 52 may be shaped as a heart (like the body shown in FIG. 2d) and the protrusion 68 may be shaped to form as letters forming the word “LOVE”. Designed shapes of the body and protrusion, messages (e.g., words) formed (e.g., printed, molded) on or in the body and protrusion, and accenting (e.g., coloring, texturing, raising and/or lowering material of the body and/or the protrusion) may be used in various combinations for a device including all together. For example, a protrusion 68 shaped to form the word “LOVE” may be colored red, include interior lines printed on the outer surface 72 of the protrusion further defining the letters, and include raised material giving the heart a rounded surface and thereby more of a three-dimensional appearance. As other examples, the body 52 and/or protrusion 68 having shapes described above, such as a foot_{b}all helmet, a dolphin, a baseball bat, etc., may also include messages and/or accenting related to the shape of the periphery. Thus, a foot_{b}all-shaped body (not shown) may be colored brown and include an elevated portion forming dimples and an elevated portion colored white forming laces of the foot_{b}all. Further, the protrusion extending from the foot_{b}all-shaped body of this example may include a shape of a mascot, such as an eagle, and the colors and interior lines further defining the eagle (e.g., forming eyes, wings, etc.).

The body 52 and/or the protrusion 68 may also include material (not shown in detail) selected to emit a desired scent or aroma. The scented material of the body 52 and/or the protrusion 68 may include a single component, such as a single fragrant oil, or may include a combination of components. Various scents may be used without departing from the scope of the present invention. For example, the scented material may emit an aroma selected from a group of aromas including floral scents, fruit scents, spices, herbs, other natural scents, and combinations of these scents. Exemplary floral scents include jasmine, lilac, lily, rose, ylang-ylang, magnolia, orchid, cherry blossom, and honeysuckle. Exemplary fruit scents include citrus, coconut, orange, banana, lemon, watermelon, cherry, strawberry or other berries, mango, watermelon, pineapple, kiwi, and grapefruit. Exemplary spices include cinnamon, coffee, and nutmeg. Exemplary herbs include rosemary, lemongrass, bergamot, chamomile, and mints such as sage, basil, oregano, thyme, peppermint, and lavender. Other natural scents include sandalwood, cucumber, patchouli, vanilla, eucalyptus, and pine. Further, the scented material may also emit other common aromas such as bubble gum, cotton candy, baby powder, musks, and chocolate. In addition, the aroma may resemble a popular perfume or cologne of a newly created perfume or cologne.

Although the scented material may have other forms, in one embodiment the scented material is in the form of a gel, a powder, or a liquid such as an oil. In one embodiment, the scented material of the body 52 is a liquid concentrate. The scented material may be added to the base material of the body 52 at various stages of development of the device 50. In one embodiment, the scented material is coated onto the outer surface 54 and/or the inner surface 56 of the body 52. Although the scented material may be coated onto the outer surface 54 and/or the inner surface 56 of the body 52 in other ways without departing from the scope of the present invention, in one embodiment the scented material is coated onto the outer surface and/or the inner surface of the body by dipping the body into a bath of the scented material, spraying the body with the scented material, or painting the body with the scented material such as by brush or other applicator. It is contemplated that the material emitting an aroma may also be part of or formed on a thin item or film such as a label or sticker attached to the outer surface 54 of the body 52.

In one embodiment, the scented material is impregnated into the body 52 during manufacture of the device 50. The scented material may be added to the base material before the base material is molded and/or cured to form the resulting shaped body 52. For example, in one embodiment the scented material in the form of an oil is added to and mixed with a liquid or gel silicone base material before molding and curing the base material to form the shaped body 52.

The molding and curing steps of forming flexible vacuum-mountable devices are well known and include positioning the base material and any processing agents into a mold, such as by injection, and setting or curing that material to form the resulting body 52. As will be apparent to those skilled in the art, an inhibitor or an accelerator may be added to the mixture forming the body 52 to control the rate and manner at which the body is molded and cures. Also, the base material of the body 52 may be vulcanized during formation by adding select chemical agents to add useful properties to the body or enhance such properties in the body including, for example, elasticity, strength, and stability. Vulcanizing materials include activators to initiate vulcanization, fillers, such as carbon, to reinforce the structure thereby enhancing chemical and mechanical properties of the body 52, vulcanization agents to cross-link polymers. Other agents that may be added to the body material to affect the formation process and characteristics of the resulting body 52 include plasticizers, which soften the material and/or improve processing, processing aids, which may ease handling during mixing, extrusion, calendaring, or molding, mold release agents, which may be coated onto the mold such as by spraying and make it easier to remove the bodies from the mold they are molded in, and age-resistors, which retard aging of the body. In addition, as described in further detail below, pigments may be added to the base material to color the body 52 as desired.

The base material and the scented material of the body 52 and the manner in which they are combined and processed affects characteristics of the device 50 such as mounting and aroma emitting characteristics. In one embodiment, the base body material is selected, the scented material is selected and added to the body 52, and the body is processed so the device 50 emits a relatively strong aroma. In another embodiment, the base material is selected, the scented material is selected and added to the body, and the body is processed so the device emits aroma for a relatively long period of time (e.g., over one year). Although emission of aroma from the body 52 may be controlled in other ways without departing from the scope of the present invention, in one embodiment the emission of aroma from the body is controlled by controlling a rate of evaporation of the scented material. The rate of evaporation or diffusion of the scented material depends on the substance of the scented material because various substances evaporate in different ways. For example, one scented material may evaporate rapidly when exposed to air, thus providing a strong aroma for a relatively shorter period of time, and another scented material may evaporate more slowly, providing an aroma for a longer period of time. Also, it is believed that the rate of evaporation may be controlled by controlling the presence and configuration of voids formed in the base material of the body 52 and channels connecting the voids to the each other and to the surface. By experimentation that is within the ability of those skilled in the art, a designer of the device 50 can select particular base materials, scented materials, and processing agents and methods to make an aromatic suction-mountable device having desired characteristics. For example, the designer may experiment with materials and processes to create a device 50 with desired performance characteristics such as ability to adhere to a variety of surfaces and emit a strong aroma for a relatively long period of time.

The aroma emitted by the scented material of the body 52 and/or the protrusion 68 may correspond to a shape of the periphery of the body and/or a shape of the periphery of the protrusion. For example, the aroma emitted by the scented material of the body 52 and/or the protrusion 68 may correspond to a message or theme communicated by the shapes of the peripheries 58, 74 of the body and/or the protrusion. In one embodiment, a butterfly-shaped body and/or protrusion (such as the body 122 and protrusion 126 shown in FIG. 4) may include material emitting a floral aroma corresponding to the shape of the body and/or the shape of the protrusion. A floral aroma relates to the butterfly shape and messages and themes related to butterflies because butterflies often land on flowers in nature. The aroma emitted by the body 52 and/or the protrusion 68 may also correspond to any of the color of the body, the color of the protrusion, the message 98 formed on or in the body and/or the protrusion, and the color of the message. For example, in one embodiment, the heart-shaped body 52 and the heart-shaped protrusion 68 shown in FIGS. 2A and 2B are colored light brown, corresponding to a lighter brown chocolate, the message 98 is colored dark brown, corresponding to a dark chocolate and includes a word “CHOCOLATE” instead of the word “LOVE” shown in the figures (resulting in a message on the device 50 of “I LOVE CHOCOLATE”), and the body and/or the protrusion include a material emitting a chocolate aroma. In this embodiment, the chocolate aroma emitted by the scented material of the body and/or the protrusion corresponds to each of the color of the body 52, the color of the protrusion 68, the message 98, and the color of the message.

FIG. 3 shows a display device 100 including a body 102 having a periphery 104 shaped as an apple. The device 100 according to this embodiment also includes a protrusion 106 having a head 108 connected to the body 102 by a stem 110. The head 108 is surrounded by a periphery 112 that is also shaped as an apple. FIG. 4 shows a display device 120 including a body 122 having a periphery 124 shaped as a butterfly. The device 120 according to this embodiment also includes a protrusion 126 having a head 128 connected to the body 122 by a stem 130. The head 128 is surrounded by a periphery 132 that is also shaped as a butterfly. FIG. 5 shows a display device 140 including a body 142 having a periphery 144 shaped as a dolphin. The device 140 according to this embodiment also includes a protrusion 146 having a head 148 connected to the body 142 by a stem 150. The head 148 is surrounded by a periphery 152 that is also shaped as a dolphin. The display devices 100, 120, 140 according to the embodiments described in this paragraph are otherwise identical to the display devices of the first embodiment.

FIG. 6 shows a display device 160, referenced above, including a body 162 having an outer surface 164, an inner surface 166 opposite the outer surface, and a periphery 168 extending around the body and surrounding the inner surface and the outer surface. The inner surface 166 includes a concave portion 170 and the outer surface 164 may include a convex portion 172. The concave portion 170 of the inner surface 166 has a center 174. The outer surface 164 includes a central portion 176 opposing (e.g., directly opposing) the center 174 of the inner surface 166. The device 160 also includes a protrusion 178 extending from the outer surface 164 of the body 162. The protrusion 178 may be connected to the outer surface 164 of the body 162 at the central portion 176 of the outer surface (as shown, for example, in the device illustrated in FIG. 2b) or at a portion of the outer surface other than the central portion 176 of the outer surface of the body, as shown in FIG. 6. The protrusion 178 includes a head 180 having an exterior surface 182, an inner or interior surface 184 opposite the exterior surface of the head, and a periphery 186 extending around the protrusion and surrounding the exterior and interior surfaces of the head. The head 180 may be connected directly to the body 162 or the protrusion 178 may include a stem 188 connecting the head and the outer surface 164 of the body, as shown in FIG. 6.

The interior surface 184 of the head 180 includes a central portion 190. The central portion 190 of the interior surface 184 of the head 180 is the portion of the interior surface that is generally at a center of area or centroid of the interior surface. The interior surface includes a portion that is directly connected to the stem 188. For example, when an entirety of an exposed portion (i.e., portion that is not directly connected to the stem 188) of the interior surface 184 is generally planer, the interior surface includes a generally planar portion abutting a generally planar upper portion of the stem. A centroid of an item (e.g., the interior surface 184 of the head 180) represented by a set of points is a point of the set of points whose coordinates (e.g., x-y coordinates or x-y-z coordinates) are the averages of the coordinates of the set of points. When the interior surface 184 is planar, the center of area would be located at about the same location as a center of mass of a very thin uniform plate (imaginary) having the same boundaries as the interior surface. As another example, if the interior surface 184 of the head 180 is flat and circular, the central portion 190 of the interior surface of the head is the portion of the interior surface that is generally at the center of the circle formed by the interior surface of the head. As yet another example, if the interior surface 184 of the head 180 is flat and rectangular, the central portion 190 is the portion of the interior surface of the head that is about halfway between the longer sides and about halfway between the shorter sides of the rectangle formed by the interior surface of the head. For embodiments in which the interior surface 184 does not have distinct sides, such as when the head 180 is generally spherical, the interior surface may be a surface of a lower part (e.g., lower half) of the head and the central portion of the interior surface is a portion of that surface defined according to the techniques described above in this paragraph. The stem 188 may be attached to the central portion 190 of the interior surface 184 of the head (as shown, for example, in the device illustrated in FIG. 2b) or to a portion of the interior surface of the head other than the central portion of the interior surface of the head. As shown in FIG. 6, the stem 188 is connected to the head 180 at a portion 272 of the interior surface 184 of the head other than the central portion 190 of the interior surface of the head and connected to the head adjacent the periphery 186 of the head adjacent a lower portion or chin area of the elephant's head.

As shown in FIG. 6, the periphery 168 of the body 162 is shaped as the body (i.e., torso, legs, feet, etc.) of an elephant and the periphery 186 of the protrusion 178 is shaped as the head of the elephant. The protrusion 178 is positioned with respect to the body 162 so that the head 180 of the protrusion forming the head of the elephant is positioned as desired (e.g., anatomically correct with respect to the elephant body) with respect the body of the device 160 forming the body of the elephant. As also shown in FIG. 6, the body 162 and the protrusion 178 include marks 192 forming details of the elephant formed by the peripheries 168, 186 including details of the eyes, mouth, ears, trunk, legs, and feet of the elephant. As described above, the markings 192 of the body 162 and/or the protrusion 178 may be printed on the outer surface 164, 182 or on the inner surface 166, 184 of the body and/or the protrusion. The marks may be printed on a label adhered to one of the outer surfaces 164, 182 and the label may be fully or partially opaque, translucent, and/or transparent as desired. The marks may also be formed using material of the flexible body 162 and/or the protrusion 178 by, for example, molding, melting, etching, or engraving. The device 160 according to this embodiment of the present invention is otherwise identical to earlier described embodiments and therefore will not be described in further detail.

FIG. 7 shows a display device 200, referenced above, including a body 202 having an outer surface 204, an inner surface 206 opposite the outer surface, and a periphery 208 extending around the body and surrounding the inner surface and the outer surface. The inner surface 206 includes a concave portion 210 and the outer surface 204 may include a convex portion 212. The concave portion 210 of the inner surface 206 has a center 214. The outer surface 204 includes a central portion 216 opposing (e.g., directly opposing) the center 214 of the inner surface 206. The device 200 also includes a protrusion 218 extending from the outer surface 204 of the body 202. As with the device shown in FIG. 6, the protrusion 218 of the device 200 of this embodiment may be attached to a central portion of the outer surface 204 of the body 202 or may be attached to a portion of the outer surface of the body other than the central portion, as shown in FIG. 7. The protrusion 218 includes a head 220 having an exterior surface 222 and a periphery 224 extending around the protrusion and surrounding the exterior surface of the head. The head 220 may be connected directly to the body 202 or the protrusion 218 may include a stem 226 connecting the head and the outer surface 204 of the body, as shown in FIG. 7.

As shown in FIG. 7, the periphery 208 of the body 202 is shaped as a foot_{b}all helmet and the periphery 224 of the protrusion 218 is shaped as a dolphin, representing the mascot of a foot_{b}all team (e.g., a high school foot_{b}all team). The protrusion 218 is positioned with respect to the body 202 so that the head 220 is positioned as desired with respect the body of the device 200. For example, in the embodiment illustrated in FIG. 7, the protrusion 218 forming the mascot is positioned on the foot_{b}all helmet formed by the body 202 adjacent where mascots are typically positioned on foot_{b}all helmets (i.e., adjacent a side or temporal area of the helmet). As also illustrated in FIG. 7, the body 202 includes marks 228 forming details of the helmet formed by the periphery 208 of the body including details of a mask, an ear hole, and an inner lining of the helmet. The device 200 according to this embodiment of the present invention is otherwise identical to earlier described embodiments.

FIG. 8 shows a display device 240, referenced above, including a body 242 having an outer surface 244, an inner surface 246 opposite the outer surface, and a periphery 248 extending around the body and surrounding the inner surface and the outer surface. The inner surface 246 includes a concave portion 250 and the outer surface 244 may include a convex portion 252. The concave portion 250 of the inner surface 246 has a center 254. The outer surface 244 includes a central portion 256 opposing (e.g., directly opposing) the center 254 of the inner surface 246. The device 240 also includes a protrusion 258 extending from the outer surface 244 of the body 242. The protrusion 258 includes a head 260 having an exterior surface 262 and a periphery 264 extending around the protrusion and surrounding the exterior surface of the head. The head 260 may be connected directly to the body 242 or the protrusion 258 may include a stem 266 connecting the head and the outer surface 244 of the body, as shown in FIG. 8.

As further shown in FIG. 8, the periphery 248 of the body 242 is shaped as an elephant and the periphery 264 of the protrusion 258 is shaped as letters forming the word “ZOO”. The periphery 264 of the protrusion 258 is positioned with respect to the body 242 so that the head 260 forming the words is positioned as desired (e.g., adjacent the body of the elephant formed by the body 242 of the device 240) with respect the body of the device. As also shown in FIG. 8, the body 242 and the protrusion 258 include marks 268 forming details of the elephant and wording formed by the peripheries 248, 264 of the body and the protrusion, respectively, including details of the eyes, trunk, ears, and feet of the elephant and details of the lettering of the wording. The device 240 according to this embodiment of the present invention is otherwise identical to earlier described embodiments.

When introducing elements of the present invention or the preferred embodiment(s) thereof, the articles “a”, “an”, “the”, and “said” are intended to mean that there are one or more of the elements. The terms “comprising”, “including”, and “having” are intended to be inclusive and mean that there may be additional elements other than the listed elements.

As various changes could be made in the above constructions without departing from the scope of the invention, it is intended that all matter contained in the above description or shown in the accompanying drawings shall be interpreted as illustrative and not in a limiting sense.

What is claimed is:

1. A deformable device mountable by suction on a generally smooth mounting surface comprising:
a body including an outer surface, a non-circular periphery extending around the body, surrounding the outer surface of the body and an inner surface opposite said outer surface having a concave portion; and
a protrusion extending from the outer surface of the body including an exterior surface having a non-circular periphery;
wherein the body is deformable from an undeformed shape to an actuated shape to mount the body on the mounting surface by positioning the inner surface of the body adjacent the mounting surface when the body is in the undeformed shape thereby forming a cavity between said concave portion and the mounting surface and deforming the body to its actuated shape thereby sealing the body against the mounting surface and forcing fluid out of the cavity to create suction between the body and the mounting surface thereby securing the body to the mounting surface.

2. A device as set forth in claim 1 wherein the periphery of the protrusion has a shape that is different from a shape of the periphery of the body.

3. A device as set forth in claim 1 wherein the periphery of the protrusion has a shape that is generally the same as a shape of the periphery of the body.

4. A device as set forth in claim 3 wherein the shape of the non-circular periphery of the protrusion and the shape of the non-circular periphery of the body are oriented in the same way.

5. A device as set forth in claim 1 wherein the protrusion has a maximum width measured between two points on its periphery between about 30% and about 100% of a maximum width of the body measured between two points on the periphery of the body.

6. A device as set forth in claim 1 wherein the body and the protrusion are unitary.

7. A device as set forth in claim 1 wherein a thickness measured between said inner surface of the body and said outer surface of the body tapers between a center of the concave portion of the inner surface and the periphery of the body.

8. A device as set forth in claim 1 wherein the protrusion includes a stem connected to the outer surface of the body and a head connected to the stem, the outer surface of the protrusion is on the head, and the periphery of the protrusion extends around the head.

9. A device as set forth in claim 8 wherein the stem has an exterior surface and a maximum width measured between two points on the exterior surface between about 10% and about 50% of a maximum width of the head measured between two points on the periphery of the protrusion.

10. A device as set forth in claim 8 wherein the outer surface of the protrusion is generally planar and generally parallel to the mounting surface when the device is mounted on the mounting surface.

11. A device as set forth in claim 10 wherein the head includes a generally planar interior surface that is opposite the outer surface of the protrusion and parallel to the outer surface of the protrusion.

12. A device as set forth in claim 11 wherein the head has a generally constant thickness measured between the outer surface of the protrusion and the interior surface of the protrusion.

13. A device as set forth in claim 11 wherein the protrusion further includes a side wall between the outer surface of the protrusion and the interior surface of the protrusion, an intersection between the side wall and the outer surface of the protrusion defines the periphery of the protrusion, and the side wall is generally perpendicular to the outer surface of the protrusion and the interior surface of the protrusion.

14. A device as set forth in claim 8 wherein the head has a maximum thickness measured between the outer surface of the protrusion and the interior surface of the protrusion between about 70% and about 100% of a maximum thickness of the body measured between the outer surface of the body and the inner surface of the body.

15. A device as set forth in claim 8 wherein the head of the protrusion and the body are separated by a minimum distance of between about 0.0875 inch and about 0.125 inch.

16. A device as set forth in claim 1 further including a message formed on or in the body and/or the protrusion.

17. A device as set forth in claim 1 wherein a shape of the periphery of the protrusion and/or a shape of the periphery of the body communicate a message.

18. A device as set forth in claim 17 wherein the shape of the periphery of the protrusion communicates a message by forming a letter and/or a number.

19. A device as set forth in claim 17 wherein the shape of the periphery of the protrusion communicates a message corresponding to the shape of the periphery of the body.

20. A device as set forth in claim 1 wherein a shape of the periphery of the protrusion corresponds to a shape of the periphery of the body.

21. A device as set forth in claim 1 wherein a shape of the periphery of the body forms at least a portion of an item and the periphery of the protrusion forms a part of the same item.

22. A device as set forth in claim 1 wherein a shape of the periphery of the protrusion and/or a shape of the periphery of the body correspond to a color of the protrusion and/or a color of the body.

23. A device as set forth in claim 1 wherein the body and/or the protrusion include material selected to emit a desired aroma.

24. A device as set forth in claim 23 wherein said aroma corresponds to at least one characteristic of the device selected from a group of characteristics consisting of a shape of the periphery of the body, a shape of the periphery of the protrusion, a color of the body, a color of the protrusion, a message formed on or in the body and/or the protrusion, and a color of said message.

25. A device as set forth in claim 1 wherein:
the protrusion includes a head, the exterior surface of the protrusion being on the head and the periphery of the protrusion extending around the head;
the head includes an interior surface opposite the outer surface of the head;
the exterior surface of the head includes a central portion; and
the head is attached to the outer surface of the body at a portion of the outer surface of the body other than the central portion of the outer surface of the body.

26. A device as set forth in claim 1 wherein:
the protrusion includes a stem connected to the outer surface of the body and a head connected to the stem, the exterior surface of the protrusion being on the head and the periphery of the protrusion extending around the head;
the head includes an interior surface opposite the outer surface of the head including a central portion; and
the stem is attached to the interior surface of the head at a portion of the interior surface of the head other than the central portion of the interior surface of the head.

27. A deformable device mountable by suction on a generally smooth mounting surface comprising:
a body including an inner surface having a concave portion, an outer surface opposite said inner surface having a central portion, a periphery extending around the body, surrounding the outer surface and the inner surface of the body; and
a protrusion extending from the outer surface of the body including a head having an interior surface, an exterior surface opposite the interior surface of the head, and a periphery extending around the head and surrounding the exterior surface, the protrusion being attached to the outer surface of the body at a portion of the outer surface of the body other than the central portion of the outer surface of the body;
wherein the body is deformable from an undeformed shape to an actuated shape to mount the body on the mounting surface by positioning the inner surface of the body adjacent the mounting surface when the body is in the undeformed shape thereby forming a cavity between said concave portion and the mounting surface and deforming the body to its actuated shape thereby sealing the body against the mounting surface and forcing fluid out of the cavity to create suction between the body and the mounting surface thereby securing the body to the mounting surface.

28. A deformable device mountable by suction on a generally smooth mounting surface comprising:
a body including an inner surface having a concave portion, an outer surface opposite said inner surface having a central portion, a periphery extending around the body, surrounding the outer surface and the inner surface of the body; and
a protrusion extending from the outer surface of the body including a stem connected to the outer surface of the body, a head having an exterior surface and an interior surface opposite the exterior surface connected to the stem, and a periphery extending around the head and surrounding the exterior and interior surfaces, the interior surface of the head including a central portion and the stem being attached to the interior surface of the head at a portion of the interior surface of the head other than the central portion of the interior surface of the head;
wherein the body is deformable from an undeformed shape to an actuated shape to mount the body on the mounting surface by positioning the inner surface of the body adjacent the mounting surface when the body is in the undeformed shape thereby forming a cavity between said concave portion and the mounting surface and deforming the body to its actuated shape thereby sealing the body against the mounting surface and forcing fluid out of the cavity to create suction between the body and the mounting surface thereby securing the body to the mounting surface.
